(19) United States
(12) Patent Application Publication
(10) Pub. No.: US 2023/0357533 A1
(43) Pub. Date: Nov. 9, 2023

(54) METHOD FOR CHEMICAL UPCYCLING OF RESINS CONTAINING ESTER BONDS

(71) Applicant: ZHEJIANG UNIVERSITY, Hangzhou (CN)

(72) Inventors: TAO XIE, HANGZHOU (CN); ZENGHE LIU, HANGZHOU (CN); NING ZHENG, HANGZHOU (CN); ZIZHENG FANG, HANGZHOU (CN); JINGJUN WU, HANGZHOU (CN)

(21) Appl. No.: 17/882,573

(22) Filed: Aug. 7, 2022

(30) Foreign Application Priority Data
May 7, 2022 (CN) 2022104917033

(51) Int. Cl. C08J 11/28; C08G 18/80; C08G 18/73; C08G 18/72; C08G 18/58; C08G 18/42; C08G 18/75; C08G 18/10

(52) U.S. Cl. CPC C08J 11/28; C08G 18/8077; C08G 18/73; C08G 18/721; C08G 18/58; C08G 18/42; C08G 18/758; C08G 18/10; C08G 18/755; C08J 2363/00; C08J 2367/06; C08J 2367/02

(57) ABSTRACT

A method for chemical upcycling of the resins containing ester bonds is described herein. The method comprises two steps: (1) The resins dissolved into a catalyst-solvent system via a network fragmentation strategy to generate non-crosslinked polymer fragment mixture with functional groups. (2) After introducing additives and reacting for predetermined time, a reconfigurable strong resin and a photocurable resin with repeated recyclability are obtained. The low energy consumption and cost, the high performance and economical value added of the regenerated productions, and the ease implement without changing the commodity products and manufacturing facilities make it attractive and suitable for the recycling of the resin wastes.

### FIELD OF TECHNOLOGY

The present invention relates to the field of resin wastes, particularly to methods for upcycling the resin wastes containing ester bonds.

### BACKGROUND TECHNOLOGY

Resins containing ester bonds, such as epoxy resin, unsaturated polyester, polyethylene terephthalate, are indispensable in our daily life owing to their robust mechanical properties, good resistance to heat, chemicals and aging. They are widely used in aerospace, electronics, medicine, transportation, building, packaging, and clothing, to meet diverse practical requirements in the form of bottle, fiber, adhesive, sealant, coating, structural component, button, etc. The large consumption of them comes with serious environmental burden after their service life.

Various approaches have been pursued to address this problem. In the past, most of the wastes end up in landfill or incineration, which not only is a huge waste of resources, but also causes secondary pollution. Therefore, these methods will not be considered in the future. Recycling is a promising method to address this problem, and can be classified into downcycling, recycling and upcycling by comparing the properties and/or economic value of regenerated productions and the original ones. Physical recycling by remolding or crushing into powders/particles as fillers is simple, but it belongs to downcycling in most circumstances due to the degraded properties and/or low economical benefit. Chemical recycling via glycolysis, aminolysis, or hydrolysis can decompose the resins into monomers, oligomers or other chemicals, which can be used for the synthesis of new materials and make it possible for recycling or upcycling the waste. However, almost all the reported works tend to realize full disintegration of polymer networks by completely breaking all the ester bonds, resulting in the requirement of harsh chemical conditions (high temperature and long reaction time). Besides, most of the reported recycled chemicals are reused for the productions similar to the original ones, which does not gain additional economical values to compensate the overall recycling cost. In recent years, an emerging method is to develop new recyclable materials by introducing reversible bonds into the polymer network and enabling the materials with solid plasticity. However, it also does not gain additional economical values. Besides, they currently cannot replace the existing resins due to their high cost and inferior performance. These factors make them difficult for large-scale practical implementation.

### SUMMARY OF THE INVENTION

The present invention discloses a method for upcycling the resins containing ester bonds. It comprises two steps: 1. The resins dissolved into a catalyst-solvent system via a network fragmentation strategy to generate non-crosslinked polymer fragment mixture with functional groups. 2. After introducing additives and reacting for predetermined time, a reconfigurable strong resin and a photocurable resin with repeated recyclability are obtained. It has the following merits: 1. The recycling condition is relatively mild, and the energy consumption and cost is low, due to the partial, rather than the typically full, disintegration of the molecular network. 2. The regenerated productions, including reconfigurable strong resin and photocurable resin, possess high performance and economical value. 3. It can be implemented easily without changing the existing productions and manufacturing facilities.

### BRIEF DESCRIPTION OF THE FIGURES

FIG. 1 shows the photographs of the resin before and after dissolution/fragmentation in Example 1.

FIG. 2 shows the shape reconfigurable ability of the regenerated resin in Example 1.

FIG. 3 shows the photograph of the 3D printing productions in Example 2 and Example 3.

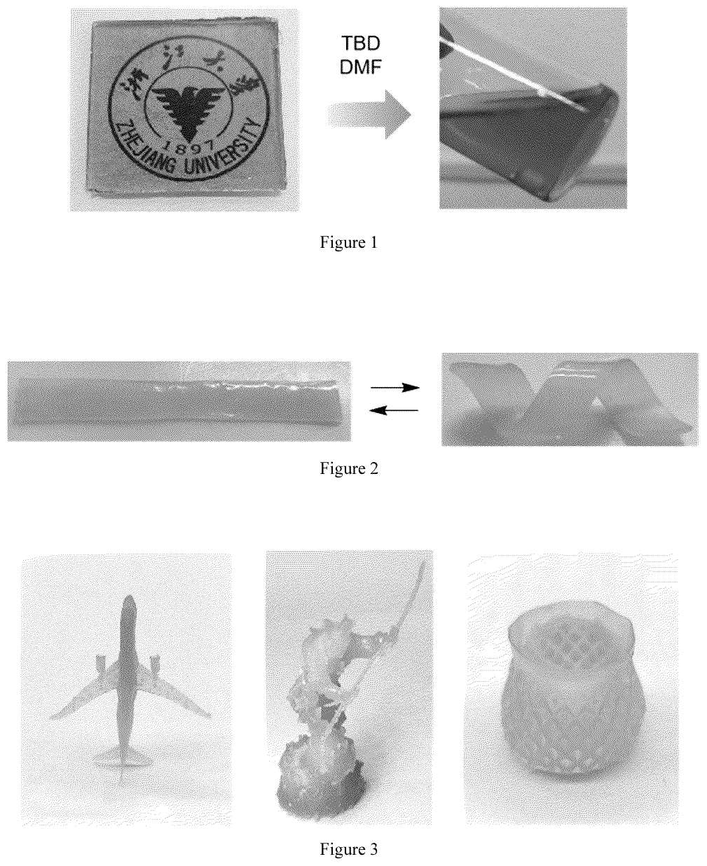

### DETAIL DESCRIPTION OF THE INVENTION

The resins as described herein includes epoxy resin, unsaturated polyester, polyethylene terephthalate, polybutylene terephthalate, etc, with ester bonds in their molecular chains.

The solvent as used herein comprises of one or more dimethylformamide, dimethylacetamide, formamide, N-methyl-2-pyrrolidone, dimethylsulfoxide, ethylene glycol, propylene glycol, ethanolamine, maleic acid, succinic acid, butanediamine, pyridine, etc. Its content is 0.5-30 times of the resin.

The catalyst as used herein comprise of one or more guanidine, amidine, amine, etc.

Preferably, the guanidine is chosen from 1,5,7-triazidebicyclo(4.4.0)dec-5-ene, tetramethylguanidine, 2-tert-butyl-1,1,3,3-tetramethylguanidine, 1,4,6-triazabicyclo[3.3.0]oct-4-ene, 7-methyl-1,5,7-triazabis[4.4.0]dec-5-ene, etc. The amidine is chosen from 1,8-diazabicycloundec-7-ene, 1,5-diazabicyclo[4.3.0]non-5-ene, propionamidine, 2-morpholinoacetamidine, chlorphenamidine, etc. The amine is chosen from triethylamine, bisdimethylaminoethyl ether, N,N-dimethylcyclohexylamine, N-ethylmorpholine, N,N-lutidine, triethylenediamine, etc. The total amount of the catalyst is 0.01-50 wt % of the solvent.

The dissolution as described herein results from the reaction of the ester bonds in the resin with the solvent and/or absorbed water in the system to disintegrate the crosslinked/macromolecular network into dissolvable fragment. The dissolution temperature and time are 50-200° C. and 5 min-10 hours, respectively.

In an embodiment for illustrating the dissolution mechanism, dimethylformamide (DMF) and 1,5,7-triazidebicyclo(4.4.0)dec-5-ene (TBD) are chosen as the solvent and catalyst, respectively. The relevant dissolution mechanism is shown below: The solvent DMF decomposes to generated dimethylamine. The generated dimethylamine and the absorbed water react with the ester bonds of the resin to form alcohol, carboxylic acid, and secondary amide groups. Accordingly, the macromolecular network of the resin is broken down into dissolvable non-crosslinked polymer fragment mixture with partially unreacted ester bonds on the backbone, and alcohol, carboxylic acid, and secondary amide groups in the terminal.

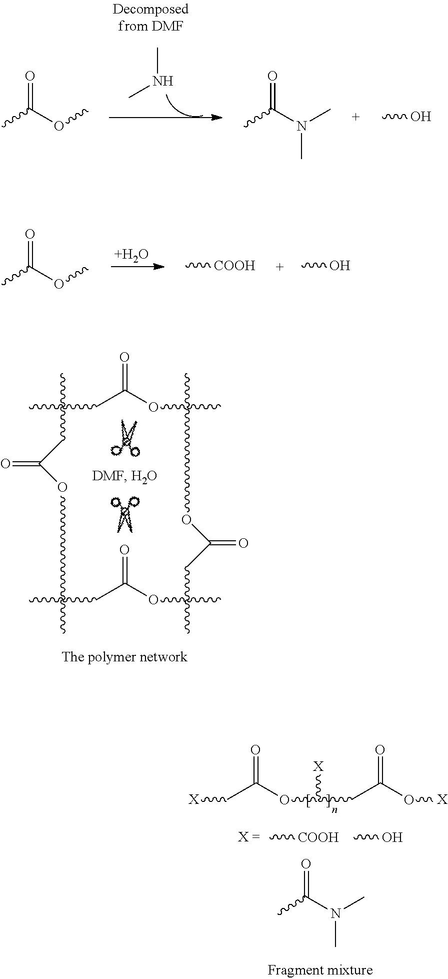

The catalytic mechanisms of the reactions during the dissolution process are shown below:
(i) Catalytic mechanism for the decomposition of DMF to generate dimethylamine.

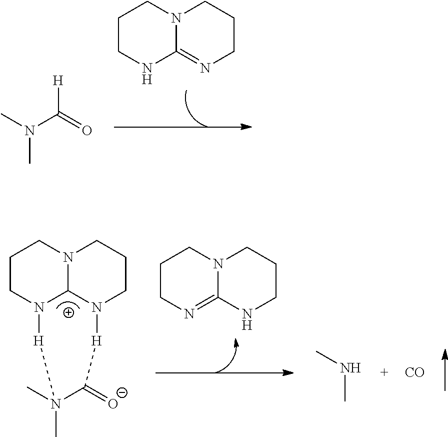

(ii) Catalytic mechanism for the reaction of ester bonds with dimethylamine.

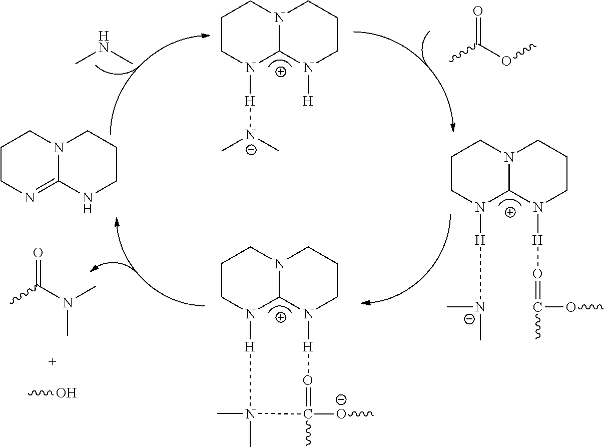

(iii) Catalytic mechanism for the reaction of ester bonds with absorbed water.

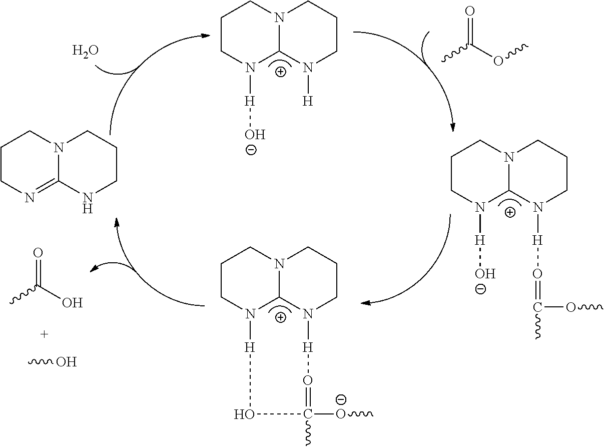

The network fragmentation as described herein refers to partially breaking down the crosslinked/macromolecular network to a point that enables reworkability, such as dissolvability or meltablity.

The fragment mixture as described herein refers to the deconstructed reworkable polymer fragments with various molecular structures (linear, branched, and/or hyperbranched), and wide molecular weight distribution (100-100,000 g/mol).

The functional groups as described herein refers to alcohol, carboxylic acid, secondary amide, and ester, etc, which can react with other reagents to reconstruct the molecular network of the fragment mixture, or can undergo bond exchange to tune the network topology.

The solvent and catalyst used herein can be recycled after the dissolution/network fragmentation via distillation, vacuum sublimation, extraction, absorption, condensation, or membrane separation, etc.

The reconfigurable strong resin and photocurable resin are prepared by the curing reaction of the fragment mixture and the additives.

The additives as used herein comprise of one or more reactive additives and non-reactive additives. The reactive additives refer to the reagents which can react with the functional groups of the fragment mixture, and/or undergo self-polymerization, and/or react with other additives. They include but are not limited to isocyanate, blocked isocyanate, epoxy, anhydride, and carbonate, acrylate/methacrylate, allyl, vinyl, thiol, polyol, amine, etc. The non-reactive additives include photoinitiator, light absorber, catalyst, etc. Their total content is 5%-50% of the fragment mixture.

Preferably, the additives consist of one or more isocyanate, blocked isocyanate, polyol, acrylate/methacrylate, photoinitiator, light absorber, catalyst, etc. The isocyanates are chosen from hexamethylene diisocyanate, diphenylmethane diisocyanate, 4,4′-Methylenebis(cyclohexyl isocyanate), tolylene diisocyanate, isophorone diisocyanate, poly(hexamethylene diisocyanate), etc. The blocking agents for the blocked isocyanate are chosen from 2-butanone oxime, acetone oxime, acetaldoxime, N-methylaniline, caprolactam, diethyl malonate, methanol, cresol, 3,5-dimethylpyrazole, etc. The polyols are chosen from poly(tetramethylene glycol), poly(propylene glycol), poly(ethylene glycol), polyhexamethylene adipate glycol, etc. The acrylates/methacrylates are chosen from 2-(tert-butylamino)ethyl methacrylate, ethylhexyl acrylate, acryloyl morpholine, urethane diacrylate, (methyl) isobornyl acrylate, tetrahydrofuran acrylate, hydroxyethyl (meth)acrylate, tripropylene glycol diacrylate, 1, 6-hexanediol diacrylate, etc. The photoinitiators are chosen from Irgacure 819, Irgacure TPO, benzophenone, benzoin dimethyl ether, 4-dimethylamino-ethyl benzoate, isopropyl thioxanthone, etc. The light absorbers are chosen from methyl red, Sudan red, Sudan black B, phthalocyanine blue, Eosin Y, etc. The catalysts are chosen from dibutyltin dilaurate, tris(dimethylaminomethyl)phenol, triethylamine, zinc acetate, etc.

The curing reaction is conducted by one or more step processes.

Preferably, the curing reaction is conducted by two steps: (i) The fragment mixture reacts with the additives at relatively low temperature to form a primary molecular network. (ii) Then, it is conducted at relatively high temperature to tune the molecular network to an optimal state, thus enables the regenerated productions with excellent mechanical properties. Specifically: pre-curing is performed first, and the pre-curing conditions are: 25-70° C. and 5 min-10 h, and then the high-temperature post-curing is performed, and the high-temperature post-curing conditions are: 100-200° C. and 5 min-10 h.

In an embodiment for illustrating the reaction mechanism of the two-step curing process, hexamethylene diisocyanate (HDI) and 2-butanone blocked diphenylmethane diisocyanate (b-MDI) are chosen as the additives for preparing the reconfigurable strong resin. Its two-step curing process is illustrated below. Firstly, it is conducted at relative temperature (<70° C.) to form a primary loose network via the reaction of the isocyanate groups in HDI with the carboxylic acid and alcohol groups in the fragment mixture to generate amide and urethane bonds. Then, it proceeds at high temperature (>100° C.) for thermal postcuring. At that temperature, b-MDI becomes active and deblocks to release MDI, which can further reacts with the generated amide and urethane bonds in the primary network to form a fully robust network.

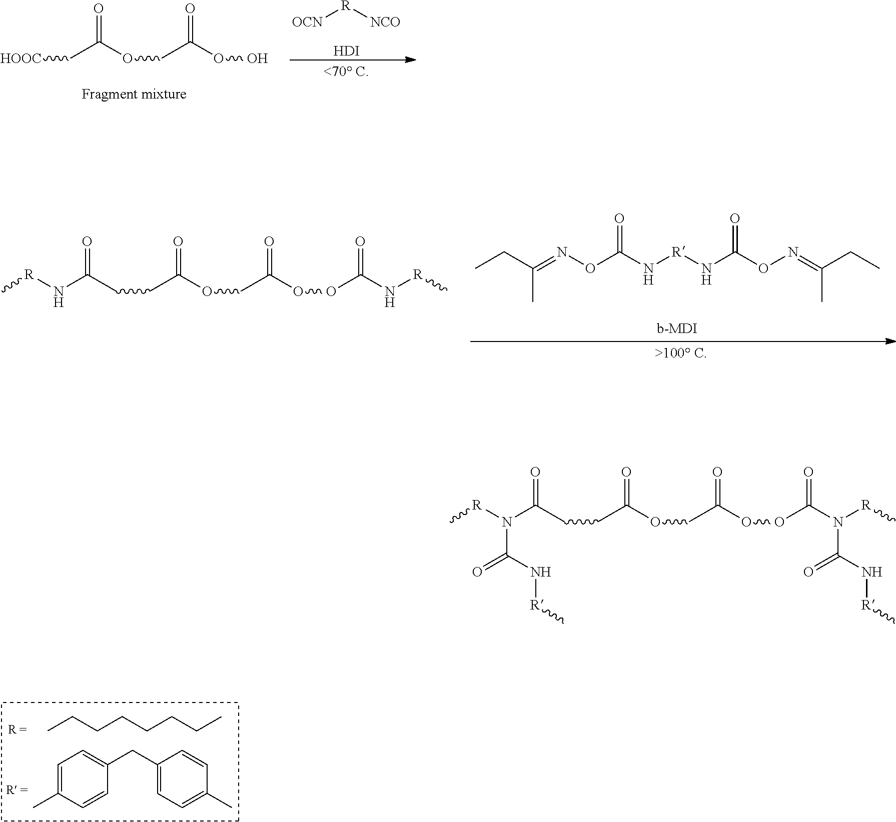

In another embodiment for illustrating the reaction mechanism of the two-step curing process, 4,4′-Methylenebis(cyclohexyl isocyanate) (HMDI) and 2-(tert-butylamino)ethyl methacrylate (TBEMA) are chosen as the additives for preparing the photocurable resin for 3D printing. The preparation of photocurable precursor is illustrated below. Firstly, the fragment mixture reacts with HMDI to generate a prepolymer with amide and urethane bonds on the backbone, and isoycanate in the terminal. Then, it reacts with EBEMA to generate a photocurable precursor (HUMA), with hindered urea dimethacrylate groups on the backbone for serving as a blocked isocyanate.

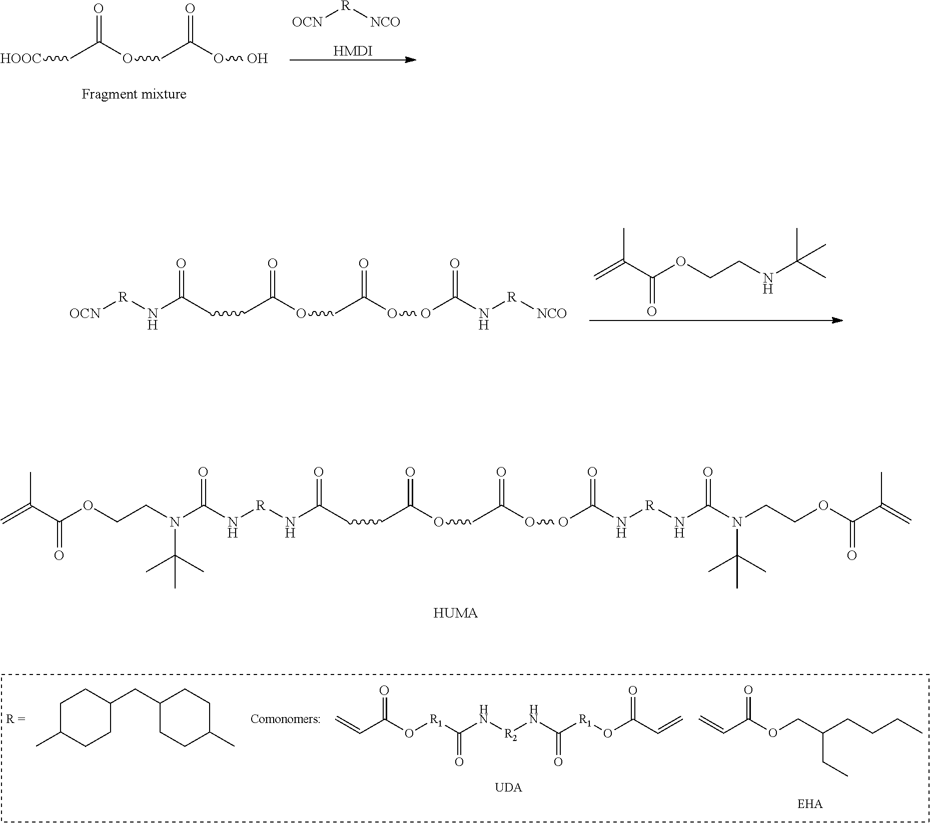

The corresponding two-step curing process of HUMA is illustrated below. Firstly, it is conducted by photocuring at ambient temperature to form a primary network. Then, it proceeded at high temperature (>100° C.) for thermal postcuring. At that temperature, the hindered urea dimethacrylate groups become active and release isocyanate, which can further react with the amide and urethane bonds in the network to form an interpenetration network. This curing method enables both of excellent mechanical property and photocuring ability, which is a challenge for the digital light processing 3D printing.

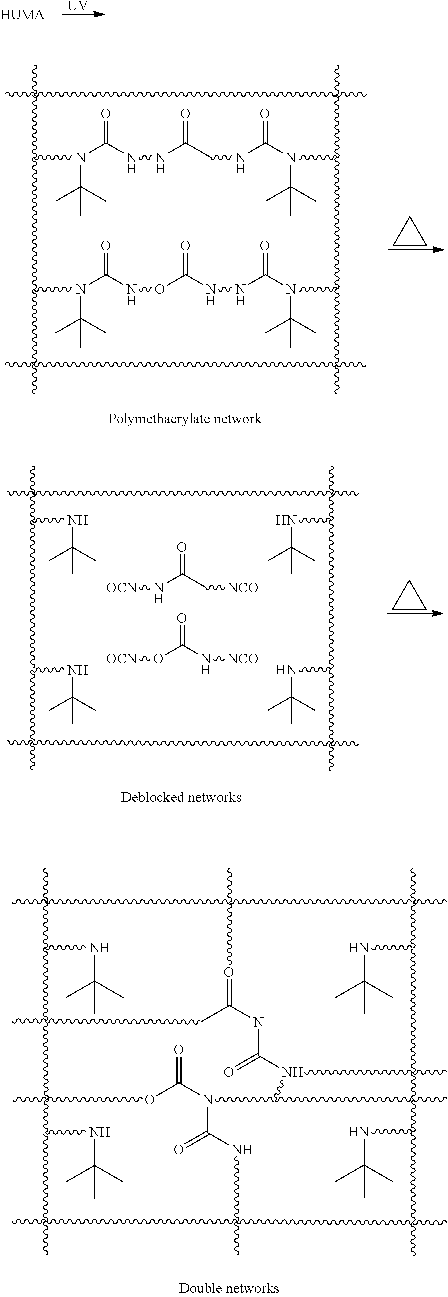

The term “reconfigurable” refers to that the shape of the regenerated productions can be reconfigured and converted to new three-dimension geometries by annealing in the presence of external loads and heating. The principle is mainly based on the exchange reaction of chemical bonds such as ester bonds, amide bonds, urethane bonds, amide-urea bonds, and allophanate bonds in the molecular network.

The photocurable resin can be applied but not limited to 3D printing, photoresist, coatings, adhesives, etc, and preferably to 3D printing.

The term “repeat recyclability” refers to that the regenerated productions can be made into new productions in the same way as the original resins.

### EXAMPLES

The following examples are intended to better illustrate the invention, but are not intended to limit the scope of the invention to the examples explicitly described.

### Example 1 Upcycling Epoxy Resin Toward Reconfigurable Strong Resin

### Raw Materials:

Bisphenol A epoxy resin (E-51); Phthalic anhydride; Tris(dimethylaminomethyl)phenol; N,N-Dimethylformamide (DMF); 1,5,7-Triazide Bicyclic (4.4.0) Dec-5-ene (TBD); Hexamethylene diisocyanate (HDI); Diphenylmethane diisocyanate (MDI); 2-Butanone oxime; Poly(propylene glycol) (PPG, Mn=2000).

### The Preparation of Epoxy Resin

E-51 (10 g), phthalic anhydride (7.5 g), and tris(dimethylaminomethyl)phenol (0.35 g) were mixed in a mold. After reacting for 1 hour at 140° C. and followed by another 1 hour at 150° C., a crosslinked epoxy resin was obtained.

### Fragmentation of the Epoxy Resin:

The epoxy resin (10 g) was immersed in DMF (ten times of the resin, containing 5% TBD) and conducted at 150° C. After two hours, the epoxy resin dissolved completely. After recycling the solvent DMF by distilling at 100° C. for about 15 minutes under vacuum, recycling the catalyst by water extraction, and drying at 120° C. for about 30 minutes, a fragment mixture (the deconstructed epoxy resin) with an averaged molecular weight of 25,700 and a polydispersity index of 1.6 was obtained.

### Preparation of Reconfigurable Strength Resin:

MDI and 2-butanone oxime with a molar ratio of 1:2 were mixed and reacted at ambient temperature for 24 hours to generate a blocked isocyanate (b-MDI). Then, b-MDI (1.6 g), HDI (0.4 g) and PPG (2 g) were added to the recycled fragment mixture (5 g) in a plate. The mixture was precured at 70° C. for about 2 hours followed by postcured at 120° C. for 1 hour, thus generating a new resin film.

### Performance Characterization:

Tensile property: The tensile strength and the breaking strain of the regenerated resin are 63.7±5.3 MPa and 20.5±1.3%, respectively.

Reconfigurable property: The regenerated resin sample can be solid-plasticized into new three-dimensional shape by reconfiguring the geometry with deformation force at 150° C. for 10 minutes.

Repeated recyclability: The regenerated resin can undergo many other rounds of recycling and reusing in the same way as the original resin. The tensile strength and breaking strain of the second regenerated resin are 57.5±7.3 MPa and 17.3±0.5%, respectively, and that of the third regenerated resin are 59.1±3.6 MPa and 19.8±2.1%, respectively.

### Example 2 Upcycling Unsaturated Polyester Toward 3D Printing Production

### Raw Materials:

Unsaturated polyester was obtained from a commercial button production line; Dimethyl Sulfoxide (DMSO); Acetone; 1,8-diazabicycloundec-7-ene (DBU); Ethylene glycol; 4,4′-Methylenebis(cyclohexyl isocyanate) (HMDI); 2-(tert-butylamino)ethyl methacrylate (TBEMA); Irgacure 819.

### Fragmentation of the Saturated Polyester:

The unsaturated polyester (100 g) was immersed in DMSO (two times of the resin, containing 10% DBU and 10% ethylene glycol) and conducted at 170° C. After two hours, the unsaturated polyester dissolved completely. After recycling DMSO, DBU and ethylene glycol by distilling at 150° C. for about 15 minutes under vacuum, a fragment mixture (the deconstructed saturated polyester) with an averaged molecular weight of 36,200 and a polydispersity index of 2.1 was obtained.

### Preparation of Photocurable Resin:

HMDI (20 g) was added to the recycled fragment mixture (70 g) with two times of acetone severing as solvent, and react at ambient temperature for 1 hour to generate a prepolymer terminated by isocyanate groups. Then, TBEMA (10 g) was added and react with the prepolymer for 1 hour to generate a hindered urea dimethacrylate precursor (HUMA), possessing hindered urea blocked isocyanate. At last, Irgacure 819 (a photoinitiator, 3%) was added to generate a photocurable precursor.

### 3D Printing and Postcuring

Here, the as-prepared photocurable precursor are used for printing a series of productions with different geometries. The exposure time of each layer was set as 30 seconds. The printed samples were washed by acetone and dried at 70° C. for 1 hour. After photo postcuring for 100 seconds and thermal postcuring at 100° C. for 2 hours, 3D printed productions with different geometries were obtained.

### Example 3 Upcycling Polyethylene Terephthalate Toward 3D Printing Production

### Raw Materials:

The polyethylene terephthalate was obtained from plastic bottles; N-methyl-2-pyrrolidone (NMP); Tetramethylguanidine (TMG); Isophorone diisocyanate (IPDI), Macklin; 2-(tert-butylamino)ethyl methacrylate (TBEMA); 2-ethylhexyl acrylate (EHA); Irgacure 819.

### Fragmentation of the Polyethylene Terephthalate:

The polyethylene terephthalate (100 g) was immersed in NMP (five times of the resin, containing 5% TMG and 5% ethylene glycol) and conducted at 150° C. After an hour, the polyethylene terephthalate dissolved completely. After recycling NMP, TMG and ethylene glycol by distilling at 150° C. for about 15 minutes under vacuum, a fragment mixture (the deconstructed polyethylene terephthalate) with an averaged molecular weight of 113,400 and a polydispersity index of 1.6 was obtained.

### Preparation of Photocurable:

IPDI (15 g) was added to the recycled fragment mixture (60 g) with two times of acetone severing as solvent, and react at ambient temperature for 1 hour to generate a prepolymer terminated by isocyanate groups. Then, TBEMA (10 g) was added and react with the prepolymer for 1 hour to generate a hindered urea dimethacrylate precursor (HUMA), possessing hindered urea blocked isocyanate. At last, EHA (a comonomer, 15 g) and Irgacure 819 (3%) was added to generate a photocurable precursor.

### 3D Printing and Postcuring

Here, the as-prepared photocurable precursor are used for printing a series of productions with different geometries. The exposure time of each layer was set as 50 seconds. The printed samples were washed by acetone and dried at 70° C. for 1 hour. After photo postcuring for 100 seconds and thermal postcuring at 100° C. for 2 hours, 3D printed productions with different geometries were obtained.

1. A method for recycling of resins containing ester bonds comprising the following steps:
(1) dissolving the resins containing ester bonds into a catalyst-solvent system to obtain non-crosslinked polymer fragment mixture with functional groups;
(2) introducing additives into the non-crosslinked polymer fragment mixture to react to obtain a reconfigurable strong resin or a photocurable resin;
wherein the catalyst is chosen from guanidine, amidine, amine;
wherein the solvent is chosen from dimethylformamide, dimethylacetamide, formamide, N-methyl-2-pyrrolidone, dimethylsulfoxide, ethylene glycol, propylene glycol, ethanolamine, maleic acid, succinic acid, butanediamine, pyridine; and
wherein the functional groups include alcohol, carboxylic acid, secondary amide, ester.

2. The method of claim 1, wherein the guanidine is chosen from 1,5,7-triazidebicyclo(4.4.0)dec-5-ene, tetramethylguanidine, 2-tert-butyl-1,1,3,3-tetramethylguanidine, 1,4,6-triazabicyclo[3.3.0]oct-4-ene, 7-methyl-1,5,7-triazabis[4.4.0]dec-5-ene.

3. The method of claim 1, wherein the amidine is chosen from 1,8-diazabicycloundec-7-ene, 1,5-diazabicyclo[4.3.0]non-5-ene, propionamidine, 2-morpholinoacetamidine, chlorphenamidine.

4. The method of claim 1, wherein the amine is chosen from triethylamine, bisdimethylaminoethyl ether, N,N-dimethylcyclohexylamine, N-ethylmorpholine, N,N-lutidine, triethylenediamine.

5. The method of claim 1, wherein the content of the catalyst is 0.01-50 wt % of the solvent.

6. The method of claim 1, wherein the content of the solvent is 0.1-30 times of the resin.

7. The method of claim 1, wherein the dissolution temperature and time are 50-200° C. and 5 min-10 hours, respectively.

8. The method of claim 1, wherein the recycled fragment mixture possesses various molecular structures (linear, branched, and/or hyperbranched) and wide molecular weight distribution (100-100,000 g/mol).

9. The method of claim 1, wherein the solvent and catalyst can be recycled via distillation, vacuum sublimation, extraction, absorption, condensation, or membrane separation.

10. The method of claim 1, wherein the additives include isocyanate, blocked isocyanate, epoxy, anhydride, carbonate, catalyst, reacting to the reconfigurable strong resin.

11. The method of claim 10, wherein the reconfigurable strong resin shape programming under external force and heating conditions.

12. The method of claim 1, wherein the additives include isocyanate, acrylate, methacrylate, allyl, vinyl, thiol, polyol, amine, photoinitiator, light absorber, catalyst, reacting to the photocurable resin.

13. The method of claim 12, wherein the photocurable resin can be applied to 3D printing, photoresist, coatings, adhesives.

14. The method of claim 10, wherein the total content of the additives is 5%-50% of the non-crosslinked polymer fragment mixture.

15. The method of claim 10, wherein, in step (2), the reaction is carried out by a two-step method: pre-curing is performed first, and the pre-curing conditions are: 25-70° C. and 5 min-10 h, and then post-curing at high temperature, the conditions for post-curing at high temperature are: 100-200° C. and 5 min-10 h.

16. The method of claim 1, wherein the reconfigurable strong resin or the photocurable resin is recycled through steps (1) and (2).

17. The method of claim 12, wherein the total content of the additives is 5%-50% of the non-crosslinked polymer fragment mixture.

18. The method of claim 12, wherein, in step (2), the reaction is carried out by a two-step method: pre-curing is performed first, and the pre-curing conditions are: 25-70° C. and 5 min-10 h, and then post-curing at high temperature, the conditions for post-curing at high temperature are: 100-200° C. and 5 min-10 h.
